(19) United States
(12) Patent Application Publication
(10) Pub. No.: US 2026/0089908 A1
(43) Pub. Date: Mar. 26, 2026

(54) SEMICONDUCTOR MEMORY DEVICE

(71) Applicant: Socionext Inc., Kanagawa (JP)

(72) Inventor: Masanobu HIROSE, Yokohama-shi (JP)

(21) Appl. No.: 19/410,318

(22) Filed: Dec. 5, 2025

Related U.S. Application Data
(63) Continuation of application No. PCT/JP2024/020654, filed on Jun. 6, 2024.

(30) Foreign Application Priority Data
Jun. 26, 2023 (JP) 2023-104374

(51) Int. Cl. H10B 10/00; G11C 5/06; H01L 23/522; H01L 23/528; H10D 30/00; H10D 30/43

(52) U.S. Cl. CPC H10B 10/12; G11C 5/063; H10D 30/43; H10D 30/502; H10W 20/42; H10W 20/427; H10W 20/43; H10W 20/435; H10W 20/498

(57) ABSTRACT

A plurality of SRAM cells include: a first SRAM cell; and a second SRAM cell aligned with the first SRAM cell in a first direction. In the first SRAM cell, lines corresponding to bit lines BLB and BL, respectively, are formed in an M1 interconnect layer that is a metal interconnect layer. In the second SRAM cell, lines corresponding to bit lines BLB and BL, respectively, are formed in a BM0 interconnect layer which is an interconnect layer on the back of a transistor.

### CROSS-REFERENCE TO RELATED APPLICATIONS

This is a continuation of International Application No. PCT/JP2024/020654 filed on Jun. 6, 2024, which claims priority to Japanese Patent Application No. 2023-104374 filed on Jun. 26, 2023. The entire disclosures of these applications are incorporated by reference herein.

p

### BACKGROUND

The present disclosure relates to a semiconductor memory device, particularly a layout structure of a static random access memory (SRAM) cell (hereinafter also simply referred to as a “cell” as appropriate).

SRAMs have been widely used for semiconductor integrated circuits.

Further, the gate length of a transistor which is a basic component of an LSI has been reduced (scaling) to improve integration degree, reduce the operating voltage, and improve the operating speed. However, an off-current due to excessive scaling and a significant increase in power consumption due to the off-current have been concerned in recent years. To address these concerns, studies have been actively conducted for a transistor having a three-dimensional structure in which a configuration of a transistor is changed from a traditional planar type to a three-dimensional type. An example of the transistor having a three-dimensional structure is a nanosheet field effect transistor (FET).

FIG. 9 of United States Patent Application Publication No. 2021/0343332 discloses a layout structure of an SRAM cell, in which: interconnect layers are provided on the back of a substrate immediately below a transistor; one of a bit line pair is provided in the back-side interconnect layer; and the other one of the bit line pair is provided in the front-side interconnect layer.

### SUMMARY

In the technique according to FIG. 9 of United States Patent Application Publication No. 2021/0343332, the bit line pair is provided in the different interconnect layers, which causes imbalance in the characteristics between the bit line pair. Since the lines of the bit line pair are provided in the different interconnect layers, process variations of the lines of the bit line pair occur independently from each other, which further increases the imbalance in the characteristics. This may reduce the yield and reliability of the SRAM cells. To avoid such a reduction, a design margin needs to be large, which may cause degradation in the performance, such as a decrease in the operating speed of the semiconductor memory device.

It is an object of the present disclosure to provide a layout structure of an SRAM cell with a line on the back of a transistor, which can reduce a degradation in the performance of a semiconductor memory device.

The present disclosure is a semiconductor memory device including a plurality of SRAM cells. Each of the SRAM cells includes: a first transistor having a source connected to a first power source for supplying a first power supply voltage, a drain connected to a first node, and a gate connected to a second node; a second transistor having a source connected to the first power source, a drain connected to the second node, and a gate connected to the first node; a third transistor having a source connected to a second power source for supplying a second power supply voltage different from the first power supply voltage, a drain connected to the first node, and a gate connected to the second node; a fourth transistor having a source connected to the second power source, a drain connected to the second node, and a gate connected to the first node; a fifth transistor having a source connected to a first bit line, a drain connected to the first node, and a gate connected to a word line; and a sixth transistor having a source connected to a second bit line forming a complementary bit line pair together with the first bit line, a drain connected to the second node, and a gate connected to the word line, the plurality of SRAM cells including: a first SRAM cell; and a second SRAM cell aligned with the first SRAM cell in a first direction, the first bit line of the first SRAM cell including a first line formed in a metal interconnect layer above the first to sixth transistors, the first line extending in a second direction, the second bit line of the first SRAM cell including a second line formed in the metal interconnect layer, the second line extending in the second direction, the first SRAM cell including: a first active region forming a channel, the source, and the drain of the third transistor of the first SRAM cell, and including a nanosheet extending in the second direction as the channel; a second active region forming a channel, the source, and the drain of the fourth transistor of the first SRAM cell, and including a nanosheet extending in the second direction as the channel; a first power supply line formed in a first back interconnect layer on a back side of the first to sixth transistors, the first power supply line extending in the second direction and connected to the second power source; a second power supply line formed in the first back interconnect layer, the second power supply line extending in the second direction and connected to the second power source; a first via arranged at a position where a first region forming the source of the third transistor in the first active region and the first power supply line overlap each other, the first via connecting the first region and the first power supply line; and a second via arranged at a position where a second region forming the source of the fourth transistor in the second active region and the second power supply line overlap each other, the second via connecting the second region and the second power supply line, the first bit line of the second SRAM cell including a third line formed in the first back interconnect layer, the third line extending in the second direction, the second bit line of the second SRAM cell including a fourth line formed in the first back interconnect layer, the fourth line extending in the second direction, the second SRAM cell including: a third active region forming a channel, the source, and the drain of the third transistor of the second SRAM cell, and including a nanosheet extending in the second direction as the channel; a fourth active region forming a channel, the source, and the drain of the fourth transistor of the second SRAM cell, and including a nanosheet extending in the second direction as the channel; a third via arranged at a position where a third region forming the source of the third transistor in the third active region and the third line overlap each other, the third via connecting the third region and the third line; a fourth via arranged at a position where a fourth region forming the source of the fourth transistor in the fourth active region and the fourth line overlap each other, the fourth via connecting the fourth region and the fourth line; and a third power supply line formed in the metal interconnect layer, the third power supply line extending in the second direction and connected to the second power source.

According to the present disclosure, in the first SRAM cell, the first and second lines corresponding to the first and second bit lines, respectively, are formed in the metal interconnect layer above the transistors. In the second SRAM cell C2, the third and fourth lines corresponding to the first and second bit lines BLB and BL, respectively, are formed in the first back interconnect layer on the back of the transistors. Thus, in the first SRAM cell and the second SRAM cell, the first and second bit lines forming the bit line pair are formed in the same interconnect layer, causing less imbalance in the characteristics between the bit line pair. Since the first and second bit lines are formed in the same interconnect layer, process variations of the lines of the bit line pair do not occur independently from each other. Accordingly, reductions in the yield and reliability of the SRAM cells are less likely to occur, requiring less design margin; therefore, degradation in the performance, such as a decrease in the operating speed of the semiconductor memory device, can be reduced.

The present disclosure provides a layout structure of an SRAM cell with a line on the back of a transistor, which can reduce a degradation in the performance of a semiconductor memory device.

### BRIEF DESCRIPTION OF THE DRAWINGS

FIG. 1 is a plan view of an example layout structure of a first SRAM cell according to an embodiment.

FIG. 2 is a cross-sectional view of the example layout structure of the first SRAM cell according to the embodiment.

FIG. 3 is another cross-sectional view of the example layout structure of the first SRAM cell according to the embodiment.

FIG. 4 is a circuit diagram showing a configuration of the SRAM cell according to the embodiment.

FIG. 5 is a plan view of an example layout structure of a second SRAM cell according to the embodiment.

FIG. 6 is a cross-sectional view of the example layout structure of the second SRAM cell according to the embodiment.

FIG. 7 is another cross-sectional view of the example layout structure of the second SRAM cell according to the embodiment.

FIG. 8 is a plan view showing an example layout of a circuit block in a semiconductor integrated circuit device according to the embodiment.

FIG. 9 is another plan view showing the example layout of the circuit block in the semiconductor integrated circuit device according to the embodiment.

FIG. 10 is a plan view of a region S1 in FIG. 9.

FIG. 11 is a cross-sectional view of the region S1 in FIG. 9.

FIGS. 12A and 12B illustrate another configuration example of the semiconductor integrated circuit device according to the embodiment.

FIG. 13 is a plan view of another example layout structure of the first SRAM cell according to the embodiment.

FIG. 14 is a plan view of another example layout structure of the second SRAM cell according to the embodiment.

FIG. 15 is a plan view of still another example layout structure of the first SRAM cell according to the embodiment.

FIG. 16 is a plan view of still another example layout structure of the second SRAM cell according to the embodiment.

### DETAILED DESCRIPTION

An embodiment will be described below with reference to the drawings. The following embodiments assume a semiconductor memory device including a plurality of SRAM cells, at least some of which include a nanosheet FET. The nanosheet FET is an FET using a thin sheet (nanosheet) through which current flows. The nanosheet is made of silicon, for example. In the present disclosure, the transistors included in the SRAM cells are not limited to the nanosheet FETs.

In this specification, “VDD” and “VSS” indicate power supply voltages or power sources themselves. In this specification, expressions indicating that the widths and the like are the same, such as “the same line width,” shall be understood to include manufacturing tolerances.

### Embodiment

The semiconductor memory device according to this embodiment includes a first SRAM cell C1 and a second SRAM cell C2.

### Configuration of First SRAM Cell

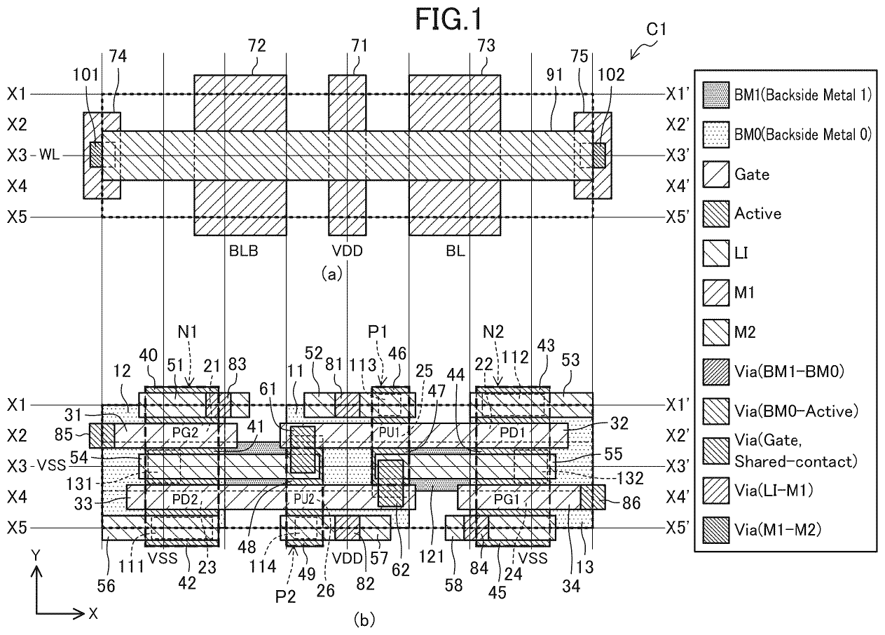

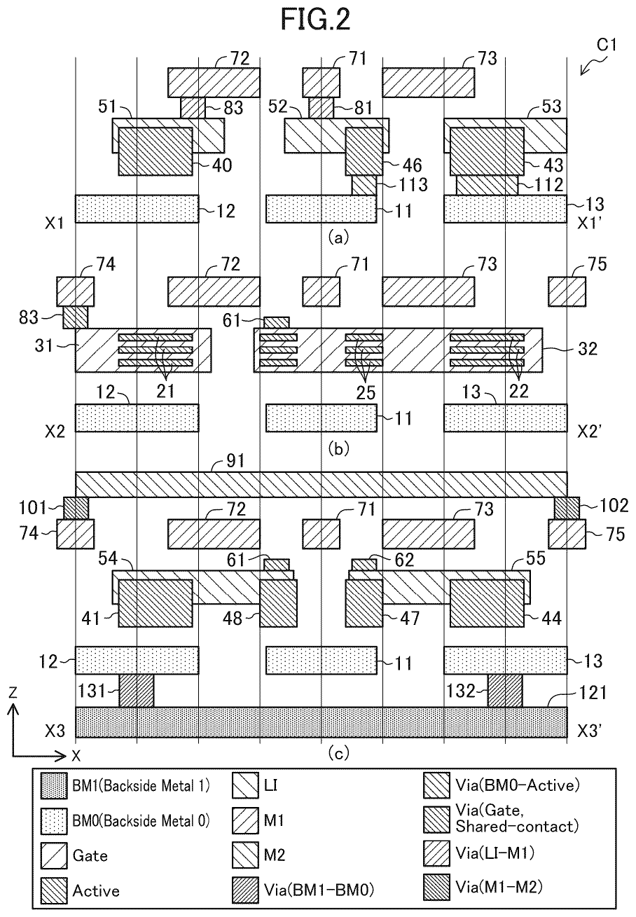

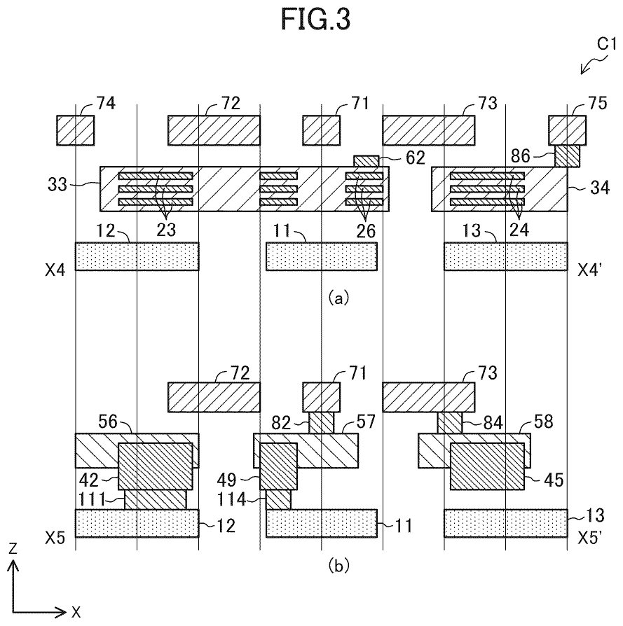

FIGS. 1 to 3 illustrate an example layout structure of the first SRAM cell according to this embodiment. (a) and (b) in FIG. 1 are plan views. (a) to (c) in FIG. 2 and (a) and (b) in FIG. 3 are cross-sectional views taken along the lateral direction in the plan view. Specifically, in FIG. 1, (a) illustrates a cell upper portion which includes M1, M2 interconnect layers, and (b) illustrates a cell lower portion which is a layer below the M1, M2 interconnect layers and includes a nanosheet FET. In FIG. 2, (a) illustrates a section taken along line X1-X1′; (b) illustrates a section taken along line X2-X2′; and (c) illustrates a section taken along line X3-X3′. In FIG. 3, (a) illustrates a section taken along line X4-X4′, and (b) illustrates a section taken along line X5-X5′.

In the following description, the lateral direction of the drawing showing the plan view, such as FIG. 1, will be referred to as the X-direction (first direction), the up-and-down direction of the drawing as the Y-direction (second direction), and the direction perpendicular to the substrate surface as the Z-direction.

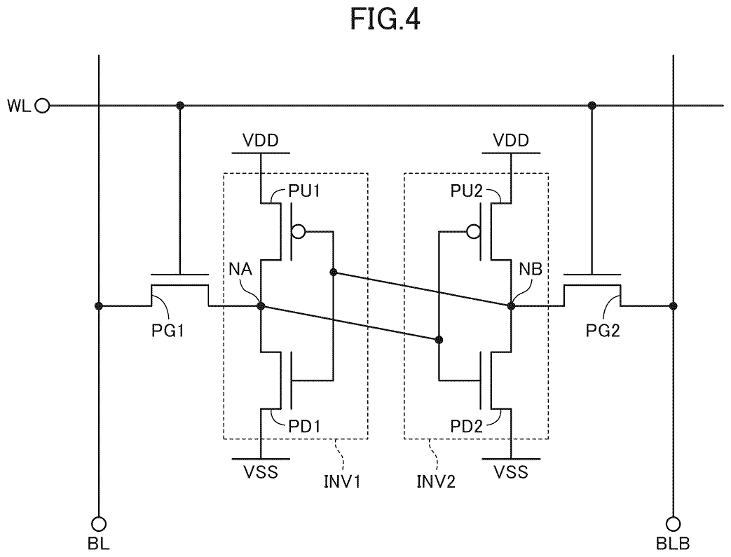

FIG. 4 is a circuit diagram showing a configuration of an SRAM cell according to this embodiment. The first SRAM cell C1 and the second SRAM cell C2 each include the SRAM circuit in FIG. 4.

As shown in FIG. 4, SRAM cells (the first SRAM cell C1 and the second SRAM cell C2) each include a SRAM circuit configured with load transistors PU1 and PU2, drive transistors PD1 and PD2, and access transistors PG1 and PG2. The load transistors PU1 and PU2 are each a P-type FET. The drive transistors PD1 and PD2 and the access transistors PG1 and PG2 are each an N-type FET.

The load transistor PU1 is provided between a power source VDD and a first node NA, and the drive transistor PD1 is provided between the first node NA and a power source VSS. The load transistor PU1 and the drive transistor PD1 have their gates connected to a second node NB to configure an inverter INV1. The load transistor PU2 is provided between the power source VDD and the second node NB, and the drive transistor PD2 is provided between the second node NB and the power source VSS. The load transistor PU2 and the drive transistor PD2 have their gates connected to the first node NA to configure an inverter INV2. That is, the output of one inverter is connected to the input of the other inverter, whereby a latch is formed.

The access transistor PG1 is provided between a bit line BL and the first node NA, and has a gate connected to a word line WL. The access transistor PG2 is provided between a bit line BLB and the second node NB, and has a gate connected to the word line WL. The bit lines BL and BLB constitute a complementary bit line pair.

In the SRAM circuit, if the bit lines BL and BLB forming the complementary bit line pair are driven to a high level and a low level, respectively, and the word line WL is driven to a high level, the high level is written to the first node NA and the low level is written to the second node NB. In contrast, if the bit lines BL and BLB are driven to a low level and a high level, respectively, and the word line WL is driven to a high level, the low level is written to the first node NA and the high level is written to the second node NB. Then, if the word line WL is driven to a low level with the data being written to the first and second nodes NA and NB, a latch state is determined and the data written to the first and second nodes NA and NB is retained.

If the bit lines BL and BLB are pre-charged to a high level and the word line WL is driven to a high level, the state of each of the bit lines BL and BLB is determined according to the data written to the first and second nodes NA and NB, and thus data can be read out from the SRAM cell. Specifically, if the first node NA is at a high level and the second node NB is at a low level, the bit line BL is held at a high level and the bit line BLB is discharged to a low level. In contrast, if the first node NA is at a low level and the second node NB is at a high level, the bit line BL is discharged to a low level and the bit line BLB maintains a high level.

As described above, the SRAM cell controls the bit lines BL and BLB and the word line WL, providing functions of writing data in the SRAM cell, retaining data, and reading out data from the SRAM cell.

In the following description, solid lines running longitudinally and laterally in the plan view shown, for example, in FIG. 1 and solid lines running longitudinally in the sectional view shown, for example, in FIG. 2 indicate grids used for arranging components at the time of designing. The grids are arranged at equal intervals in the X-direction, and are arranged at equal intervals in the Y-direction. The intervals of the grids in the X-direction and those in the Y-direction may be the same or different. The intervals of the grids may be different among layers. Further, each component is not necessarily disposed on the grid.

Dotted lines surrounding the cell in the plan view shown, for example, in FIG. 1 indicate a cell frame of the SRAM cell (outer edge of the SRAM cell). The SRAM cell is disposed such that its cell frame comes into contact with a cell frame of an adjacent cell in the X-direction or the Y-direction.

As shown in (b) in FIG. 1, a backside metal 0 (BM0) interconnect layer and a backside metal 1 (BM1) interconnect layer, which are interconnect layers, are formed on the back of the semiconductor chip where a transistor is formed. The BM1 interconnect layer is provided below the BM0 interconnect layer, that is, farther from the transistor. The BM0 interconnect layer corresponds to a first back interconnect layer, and the BM1 interconnect layer corresponds to a second back interconnect layer.

The BM0 interconnect layer is provided with power supply lines 11 to 13 extending in the Y-direction between both the upper and lower ends of the cell. The power supply line 11 supplies the power supply voltage VDD. The power supply lines 12 and 13 supply the power supply voltage VSS.

The BM1 interconnect layer is provided with a power supply line 121 extending in the X-direction between both the right and left ends of the cell. The power supply line 121 supplies the power supply voltage VSS. The power supply line 121 is connected to the power supply line 12 through a via 131 and connected to the power supply line 13 through a via 132.

A plurality of active regions forming the channel, the source, and the drain of an N-type transistor are formed in an N-type transistor region on a P-type substrate (PSub) (not shown). Specifically, active regions N1 and N2 are formed in the N-type transistor region. The active regions N1 and N2 overlap the power supply lines 12 and 13, respectively, in plan view.

In the N-type transistor region, the access transistor PG2, the drive transistor PD1, the drive transistor PD2, and the access transistor PG1 are formed. The access transistor PG2, the drive transistor PD1, the drive transistor PD2, and the access transistor PG1 have, as a channel, nanosheets 21 to 24, respectively, each of which has a triple-sheet structure overlapping one another in plan view and extends in the Y-direction. That is, the access transistor PG2, the drive transistor PD1, the drive transistor PD2, and the access transistor PG1 are nanosheet FETs.

In the active region N1, the portion (i.e., a region 42) to serve as the source of the drive transistor PD2 is connected to the power supply line 12 through a via 111 provided at a position overlapping the power supply line 12 in plan view. In the active region N2, the portion (i.e., a region 43) to serve as the source of the drive transistor PD1 is connected to the power supply line 13 through a via 112 provided at a position overlapping the power supply line 13 in plan view.

A plurality of active regions forming the channel, the source, and the drain of a P-type transistor are formed in a P-type transistor region on an N-type well (NWell) (not shown). Specifically, active regions P1 and P2 are formed in the P-type transistor region. The active regions P1 and P2 overlap the power supply line 11 in plan view.

In the P-type transistor region, the load transistors PU1 and PU2 are formed. The load transistors PU1 and PU2 have, as a channel, nanosheets 25 and 26, respectively, each of which has a triple-sheet structure overlapping one another in plan view and extends in the Y-direction. That is, the load transistors PU1 and PU2 are nanosheet FETs. The nanosheets 21 to 24 have a width in the X-direction twice the width of the nanosheets 25 and 26 in the X-direction.

In the active region P1, the portion (i.e., a region 46) to serve as the source of the load transistor PU1 is connected to the power supply line 11 through a via 113 provided at a position overlapping the power supply line 11 in plan view. In the active region P2, the portion (i.e., a region 49) to serve as the source of the load transistor PU2 is connected to the power supply line 12 through a via 114 provided at a position overlapping the power supply line 12 in plan view.

As shown in (b) of FIG. 1, gate lines (Gate) 31 to 34 extending in the X-direction are formed. The gate line 31 surrounds the outer periphery of the nanosheet 21 in the X-direction and the Z-direction. The gate line 32 surrounds the outer periphery of the nanosheets 25 and 22 in the X-direction and the Z-direction. The gate line 33 surrounds the outer periphery of the nanosheets 23 and 26 in the X-direction and the Z-direction. The gate line 34 surrounds the outer periphery of the nanosheet 24 in the X-direction and the Z-direction. The gate line 31 corresponds to the gate of the access transistor PG2. The gate line 32 corresponds to the gates of the load transistor PU1 and the drive transistor PD1. The gate line 33 corresponds to the gates of the drive transistor PD2 and the load transistor PU2. The gate line 34 corresponds to the gate of the access transistor PG1.

The local interconnect layer is provided with local lines 51 to 58 extending in the X-direction. The local line 51 is connected to a region 40 in the active region N1. The local line 52 is connected to the region 46 in the active region P1. The local line 53 is connected to the region 43 in the active region N2. The local line 54 is connected to a region 41 in the active region N1 and a region 48 in the active region P2. The local line 55 is connected to a region 47 in the active region P1 and a region 44 in the active region N2. The local line 56 is connected to the region 42 in the active region N1. The local line 57 is connected to the region 49 in the active region P2. The local line 58 is connected to a region 45 in the active region N2.

The region 40 is a portion of the active region N1 that serves as the source of the access transistor PG2. The region 41 is a portion of the active region N1 that serves as the drain of the access transistor PG2 and the drain of the drive transistor PD2. The region 42 is a portion of the active region N1 that serves as the source of the drive transistor PD2. The region 43 is a portion of the active region N2 that serves as the source of the drive transistor PD1. The region 44 is a portion of the active region N2 that serves as the drain of the drive transistor PD1 and the drain of the access transistor PG1. The region 45 is a portion of the active region N2 that serves as the source of the access transistor PG1. The region 46 is a portion of the active region P1 that serves as the source of the load transistor PU1. The region 47 is a portion of the active region P1 that serves as the drain of the load transistor PU1. The region 48 is a portion of the active region P2 that serves as the drain of the load transistor PU2. The region 49 is a portion of the active region P2 that serves as the source of the load transistor PU2.

The local line 54 is connected to the gate line 32 through a shared-contact 61. The local line 55 is connected to the gate line 33 through a shared-contact 62. The gate line 33, the local line 55, and the shared-contact 62 correspond to the first node NA. The gate line 32, the local line 54, and the shared-contact 61 correspond to the second node NB.

As shown in (a) in FIG. 1, the M1 interconnect layer, which is a metal interconnect layer above the local interconnect layer, is provided with a power supply line 71 and lines 72 and 73 extending in the Y-direction between both the upper and lower ends of the cell in the drawing. Further, lines 74 and 75 are formed. The power supply line 71 supplies the power supply voltage VDD. The lines 72 and 73 correspond to the bit lines BLB and BL. The power supply line 71 includes a portion overlapping the power supply line 11. The line 72 includes portions overlapping the active region N1 and the power supply line 12 in plan view. The line 73 includes portions overlapping the active region N2 and the power supply line 13 in plan view.

The power supply line 71 is connected to the local line 52 through a via 81, and connected to the local line 57 through a via 82. The line 72 is connected to the local line 51 through a via 83. The line 73 is connected to the local line 58 through a via 84. The line 74 is connected to the gate line 31 through a contact (Gate-contact) 85. The line 75 is connected to the gate line 34 through a contact 86.

A line 91 extending in the X-direction from the left end to the right end of the cell in the drawing is formed in the M2 interconnect layer located above the M1 interconnect layer. The line 91 corresponds to the word line WL. The line 91 is connected to the line 74 through a via 101, and is connected to the line 75 through a via 102.

With the above configuration, the BM0 interconnect layer, which is an interconnect layer on the back of the transistors, is provided with the power supply lines 12 and 13 for supplying the power supply voltage VSS. Accordingly, it is not necessary to form a power supply line for supplying the power supply voltage VSS in the M1 interconnect layer, which is a metal interconnect layer; therefore, the line widths of the lines 72 and 73 corresponding to the bit lines BLB and BL, respectively, can be increased. This can reduce the line resistances of the bit lines and thus can reduce lowering of the operating speed of the semiconductor memory device.

The M1 interconnect layer is provided with the lines 72 and 73 corresponding to the bit lines BLB and BL, respectively. The BM0 interconnect layer is provided with the power supply lines 12 and 13 for supplying the power supply voltage VSS. Accordingly, it is not necessary to form lines corresponding to the bit lines BLB and BL in the BM0 interconnect layer; therefore, the line widths of the power supply lines 12 and 13, in the BM0 interconnect layer, for supplying the power supply voltage VSS can be increased. This can reduce the line resistances of the power supply lines; therefore, it is possible to reduce the fluctuation of the power supply voltage, reduce lowering of the operating speed of the semiconductor memory device, and increase the stability of the operation.

The BM0 interconnect layer and the M1 interconnect layer are provided with the power supply lines 11 and 71 for supplying the power supply voltage VDD, respectively. This can reduce the line width of the power supply line 11 formed in the BM0 interconnect layer and increase the line widths of the power supply lines 12 and 13 for supplying the power supply voltage VSS; it is thus possible to reduce the line resistances of the power supply lines. This can reduce the fluctuation of the power supply voltage, and can thus reduce lowering of the operating speed of the semiconductor memory device and increase the stability of the operation.

The power supply line 71 for supplying the power supply voltage VDD is formed between the line 72 and the line 73. This reduces the crosstalk noise between the lines 72 and 73 corresponding to the bit lines BLB and BL, respectively, which can reduce degradation in the performance and decrease in the reliability of the semiconductor memory device.

### Second SRAM Cell

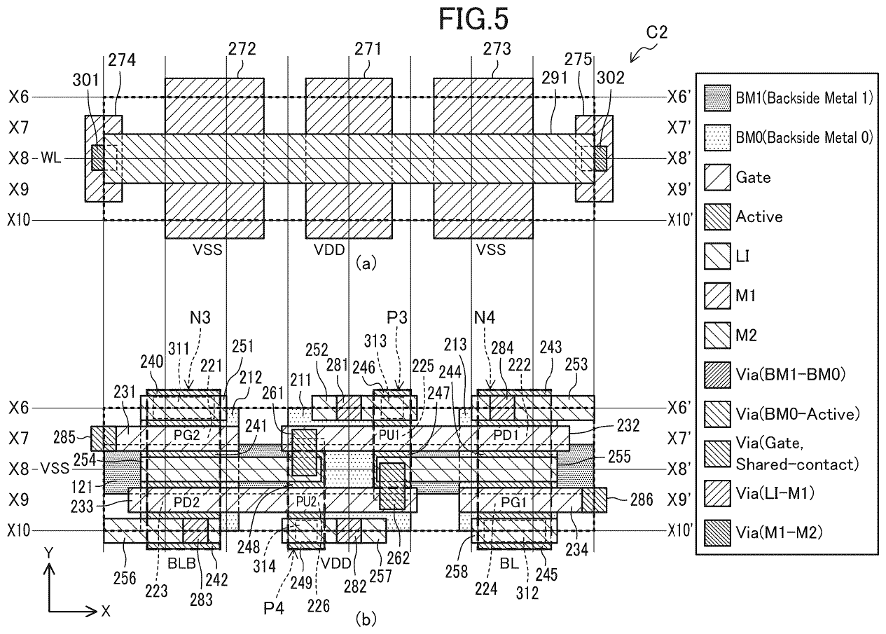

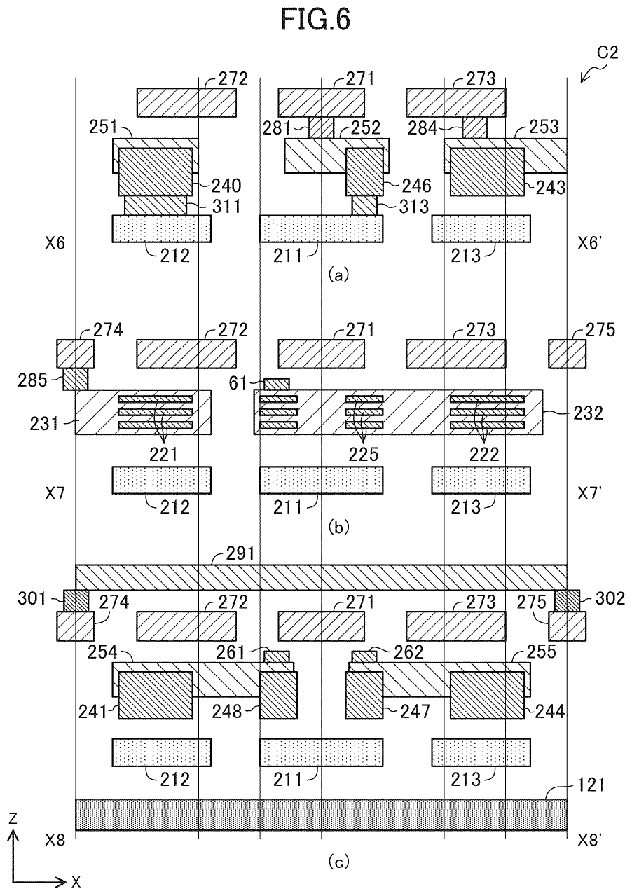

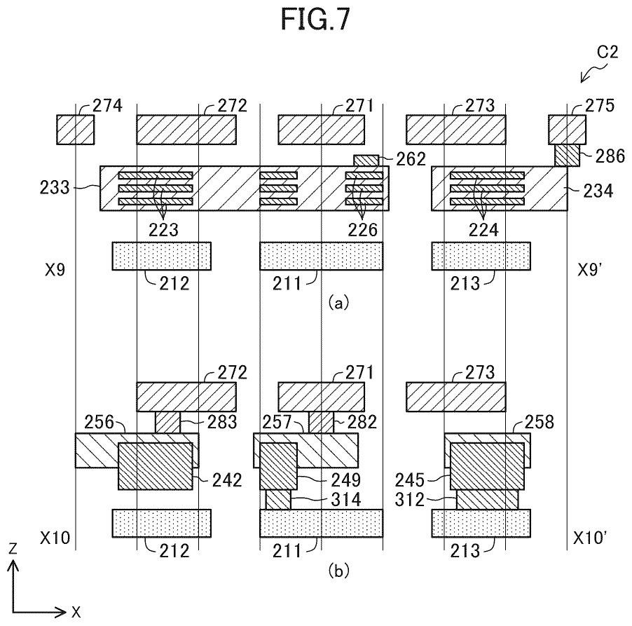

FIGS. 5 to 7 show an example layout structure of the second SRAM cell according to this embodiment. Specifically, in FIG. 5, (a) illustrates a cell upper portion, and (b) illustrates a cell lower portion. In FIG. 6, (a) illustrates a section taken along line X6-X6′; (b) illustrates a section taken along line X7-X7′; and (c) illustrates a section taken along line X8-X8′. In FIG. 7, (a) illustrates a section taken along line X9-X9′, and (b) illustrates a section taken along line X10-X10′.

As described above, the second SRAM cell C2 includes the SRAM circuit in FIG. 4.

As shown in (b) of FIG. 5, the BM0 interconnect layer is provided with a power supply line 211 and lines 212 and 213 extending in the Y-direction between both the upper and lower ends of the cell. The power supply line 211 supplies the power supply voltage VDD. The lines 212 and 213 correspond to the bit lines BLB and BL, respectively.

The BM1 interconnect layer is provided with the power supply line 121 extending in the X-direction between both the right and left ends of the cell. The power supply line 121 supplies the power supply voltage VSS. The power supply line 121 is not connected to any lines, transistors, or other components in the second SRAM cell C2.

A plurality of active regions forming the channel, the source, and the drain of an N-type transistor are formed in an N-type transistor region on a P-type substrate (not shown). Specifically, active regions N3 and N4 are formed in the N-type transistor region. The active regions N3 and N4 overlap the lines 212 and 213, respectively, in plan view.

In the N-type transistor region, the access transistor PG2, the drive transistor PD1, the drive transistor PD2, and the access transistor PG1 are formed. The access transistor PG2, the drive transistor PD1, the drive transistor PD2, and the access transistor PG1 have, as a channel, nanosheets 221 to 224, respectively, each of which has a triple-sheet structure overlapping one another in plan view and extends in the Y-direction. That is, the access transistor PG2, the drive transistor PD1, the drive transistor PD2, and the access transistor PG1 are nanosheet FETs.

In the active region N3, the portion (i.e., a region 240) to serve as the source of the access transistor PG2 is connected to the line 212 through a via 311 provided at a position overlapping the line 212 in plan view. In the active region N4, the portion (i.e., a region 245) to serve as the source of the access transistor PG1 is connected to the line 213 through a via 312 provided at a position overlapping the line 213 in plan view.

A plurality of active regions forming the channel, the source, and the drain of a P-type transistor are formed in a P-type transistor region on an N-type well (not shown). Specifically, active regions P3 and P4 are formed in the P-type transistor region. The active regions P3 and P4 overlap the power supply line 211 in plan view.

In the P-type transistor region, the load transistors PU1 and PU2 are formed. The load transistors PU1 and PU2 have, as a channel, nanosheets 225 and 226, respectively, each of which has a triple-sheet structure overlapping one another in plan view and extends in the Y-direction. That is, the load transistors PU1 and PU2 are nanosheet FETs. The nanosheets 221 to 224 have a width in the X-direction twice the width of the nanosheets 225 and 226 in the X-direction.

As shown in (b) of FIG. 5, gate lines (Gate) 231 to 234 extending in the X-direction are formed. The gate line 231 surrounds the outer periphery of the nanosheet 221 in the X-direction and the Z-direction. The gate line 232 surrounds the outer periphery of the nanosheets 225 and 222 in the X-direction and the Z-direction. The gate line 233 surrounds the outer periphery of the nanosheets 223 and 226 in the X-direction and the Z-direction. The gate line 234 surrounds the outer periphery of the nanosheet 224 in the X-direction and the Z-direction. The gate line 231 corresponds to the gate of the access transistor PG2. The gate line 232 corresponds to the gates of the load transistor PU1 and the drive transistor PD1. The gate line 233 corresponds to the gates of the drive transistor PD2 and the load transistor PU2. The gate line 234 corresponds to the gate of the access transistor PG1.

The local interconnect layer is provided with local lines 251 to 258 extending in the X-direction. The local line 251 is connected to the region 240 in the active region N3. The local line 252 is connected to a region 246 in the active region P3. The local line 253 is connected to a region 243 in the active region N4. The local line 254 is connected to a region 241 in the active region N3 and a region 248 in the active region P4. The local line 255 is connected to a region 247 in the active region P3 and a region 244 in the active region N4. The local line 256 is connected to a region 242 in the active region N3. The local line 257 is connected to a region 249 in the active region P4. The local line 258 is connected to the region 245 in the active region N4.

The region 240 is a portion of the active region N3 that serves as the source of the access transistor PG2. The region 241 is a portion of the active region N3 that serves as the drain of the access transistor PG2 and the drain of the drive transistor PD2. The region 242 is a portion of the active region N3 that serves as the source of the drive transistor PD2. The region 243 is a portion of the active region N4 that serves as the source of the drive transistor PD1. The region 244 is a portion of the active region N4 that serves as the drain of the drive transistor PD1 and the drain of the access transistor PG1. The region 245 is a portion of the active region N4 that serves as the source of the access transistor PG1. The region 246 is a portion of the active region P3 that serves as the source of the load transistor PU1. The region 247 is a portion of the active region P3 that serves as the drain of the load transistor PU1. The region 248 is a portion of the active region P4 that serves as the drain of the load transistor PU2. The region 249 is a portion of the active region P4 that serves as the source of the load transistor PU2.

The local line 254 is connected to the gate line 232 through a shared-contact 261. The local line 255 is connected to the gate line 233 through a shared-contact 262. The gate line 233, the local line 255, and the shared-contact 262 correspond to the first node NA. The gate line 232, the local line 254, and the shared-contact 261 correspond to the second node NB.

As shown in (a) in FIG. 5, the M1 interconnect layer is provided with power supply lines 271 to 273 extending in the Y-direction between both the upper and lower ends of the cell in the drawing. Further, lines 274 and 275 are formed. The power supply line 271 supplies the power supply voltage VDD. The power supply lines 272 and 273 supply the power supply voltage VSS. The power supply line 271 overlaps the active regions P3 and P4 and the power supply line 211 in plan view. The power supply line 272 overlaps the active region N3 and the line 212 in plan view. The power supply line 273 overlaps the active region N4 and the line 213 in plan view.

The power supply line 271 is connected to the local line 252 through a via 281, and connected to the local line 257 through a via 282. The power supply line 272 is connected to the local line 256 through a via 283. The power supply line 273 is connected to the local line 253 through a via 284. The line 274 is connected to the gate line 231 through a contact 285. The line 275 is connected to the gate line 234 through a contact 286.

The M2 interconnect layer is provided with a line 291 extending in the X-direction between both the right and left ends of the cell in the drawing. The line 291 corresponds to the word line WL. The line 291 is connected to the line 274 through a via 301, and is connected to the line 275 through a via 302.

With the above configuration, the M1 interconnect layer, which is a metal interconnect layer, is provided with the power supply lines 272 and 273 for supplying the power supply voltage VSS. Accordingly, it is not necessary to form a power supply line for supplying the power supply voltage VSS in the BM0 interconnect layer, which is an interconnect layer on the back of the transistors; therefore, the line widths of the lines 212 and 213 corresponding to the bit lines BLB and BL, respectively, can be increased. This can reduce the line resistances of the bit lines and thus can reduce lowering of the operating speed of the semiconductor memory device.

The M1 interconnect layer is provided with the power supply lines 272 and 273 for supplying the power supply voltage VSS. The BM0 interconnect layer is provided with the lines 212 and 213 corresponding to the bit lines BLB and BL, respectively. Accordingly, it is not necessary to form lines corresponding to the bit lines BLB and BL in the M1 interconnect layer; therefore, the line widths of the power supply lines 272 and 273, in the M1 interconnect layer, for supplying the power supply voltage VSS can be increased. This can reduce the line resistances of the power supply lines; therefore, it is possible to reduce the fluctuation of the power supply voltage, reduce lowering of the operating speed of the semiconductor memory device, and increase the stability of the operation.

The BM0 interconnect layer and the M1 interconnect layer are provided with the power supply lines 211 and 271 for supplying the power supply voltage VDD, respectively. This can reduce the line width of the power supply line 271 formed in the M1 interconnect layer and increase the line widths of the power supply lines 272 and 273 for supplying the power supply voltage VSS; it is thus possible to reduce the line resistances of the power supply lines. This can reduce the fluctuation of the power supply voltage, and can thus reduce lowering of the operating speed of the semiconductor memory device and increase the stability of the operation.

The power supply line 211 for supplying the power supply voltage VDD is formed between the line 212 and the line 213. This reduces the crosstalk noise between the lines 212 and 213 corresponding to the bit lines BLB and BL, respectively, which can reduce degradation in the performance and decrease in the reliability of the semiconductor memory device.

### Configuration of Circuit Block

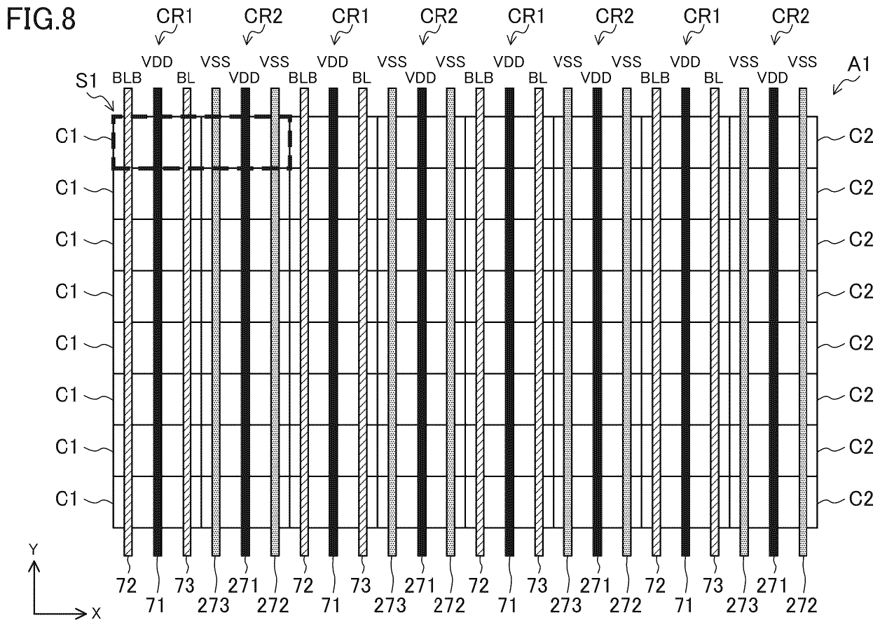

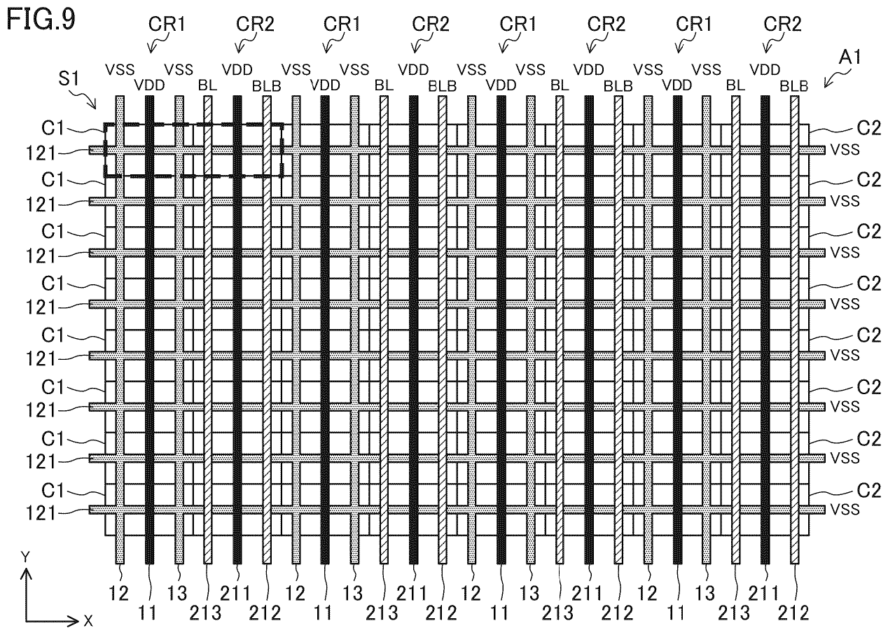

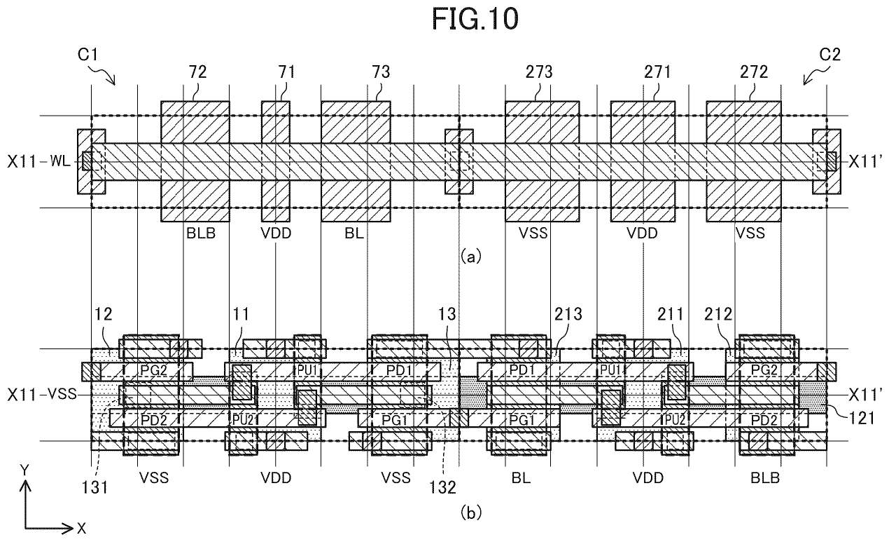

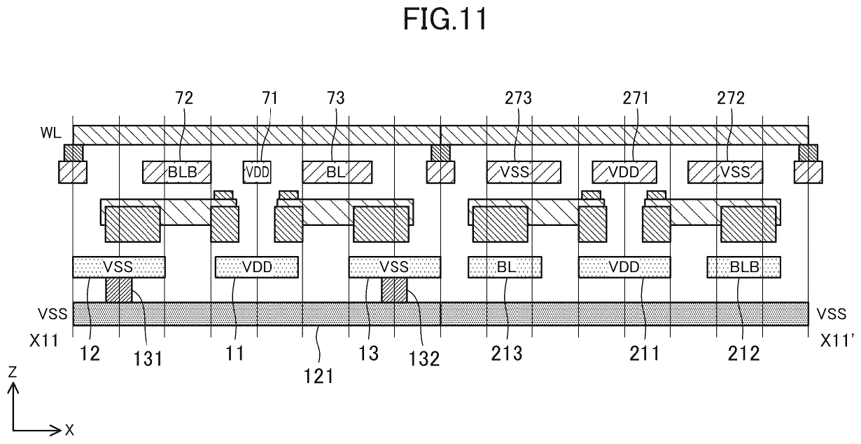

FIGS. 8 to 11 show an example layout of a circuit block in a semiconductor integrated circuit device according to the embodiment. Specifically, FIG. 8 is a plan view of the M1 interconnect layer in the circuit block. FIG. 9 is a plan view of the BM0 interconnect layer and the BM1 interconnect layer in the circuit block. In FIG. 10, (a) is a plan view of a cell upper portion of a region S1 in FIGS. 8 and 9. In FIG. 10, (b) is a plan view of a cell lower portion of the region S1 in FIGS. 8 and 9. FIG. 11 illustrates a section taken along line X11-X11′ in FIG. 10. In FIG. 8, only the cell frames of SRAM cells and the lines in the M1 interconnect layer are shown. In FIG. 9, only the cell frames of SRAM cells and the lines in the BM0 interconnect layer and the BM1 interconnect layer are shown.

A memory cell array A1 is formed in the circuit block in FIGS. 8 and 9. In the memory cell array A1, cell rows CR1 and cell rows CR2 are aligned alternately in the X-direction. Each cell row CR1 includes a plurality of first SRAM cells C1 aligned in the Y-direction. Each cell row CR2 includes a plurality of second SRAM cells C2 aligned in the Y-direction. In FIGS. 8 and 9, the second SRAM cells C2 of FIG. 5 inverted in the X-direction are arranged in each of the cell rows CR2.

As shown in FIG. 8, in each of the cell rows CR1, the plurality of first SRAM cells C1 aligned in the Y-direction in the M1 interconnect layer are connected in common to the power supply line 71 (i.e., the power supply line for supplying the power supply voltage VDD) and the lines 72 and 73 (i.e., the bit lines BLB and BL) extending in the Y-direction. In each of the cell rows CR2, the plurality of second SRAM cells C2 aligned in the Y-direction in the M1 interconnect layer are connected in common to the power supply line 271 (i.e., the power supply line for supplying the power supply voltage VDD) and the power supply lines 272 and 273 (i.e., the power supply lines for supplying the power supply voltage VSS) extending in the Y-direction.

As shown in FIG. 8 and (a) of FIG. 10, the lines in the M1 interconnect layer are aligned in the X-direction in the order of the line 72, the power supply line 71, the line 73, the power supply line 273, the power supply line 271, and the power supply line 272 from the left to the right in the drawings.

As shown in FIG. 9, in each of the cell rows CR1, the plurality of first SRAM cells C1 aligned in the Y-direction in the BM0 interconnect layer are connected in common to the power supply line 11 (i.e., the power supply line for supplying the power supply voltage VDD) and the power supply lines 12 and 13 (i.e., the power supply lines for supplying the power supply voltage VSS) extending in the Y-direction. In each of the cell rows CR2, the plurality of second SRAM cells C2 aligned in the Y-direction in the BM0 interconnect layer are connected in common to the power supply line 211 (i.e., the line for supplying the power supply voltage VDD) and the lines 212 and 213 (i.e., the bit lines BLB and BL) extending in the Y-direction. In the BM1 interconnect layer, a plurality of power supply lines 121 (i.e., power supply lines for supplying the power supply voltage VSS) extending in the X-direction are aligned in the Y-direction, and the power supply lines 121 are connected to the power supply lines 12 and 13 in the BM0 interconnect layer through the vias 131 and 132 (not shown in FIG. 9), respectively.

As shown in FIG. 9 and (b) of FIG. 10, the lines in the BM1 interconnect layer are aligned in the X-direction in the order of the power supply line 12, the power supply line 11, the power supply line 13, the line 213, the power supply line 211, and the line 212 from the left to the right in the drawings.

With the above configuration, in the circuit block according to this embodiment, in each first SRAM cell C1, the lines 72 and 73 corresponding to the bit lines BLB and BL, respectively, are formed in the M1 interconnect layer that is a metal interconnect layer. In each second SRAM cell C2, the lines 212 and 213 corresponding to bit lines BLB and BL, respectively, are formed in the BM0 interconnect layer that is an interconnect layer on the back of transistors. Accordingly, in each of the first SRAM cells C1 and the second SRAM cell C2, the bit lines BL and BLB forming the bit line pair are formed in the same interconnect layer, causing less imbalance in the characteristics between the bit line pair. Since the bit lines BLB and BL are formed in the same interconnect layer, process variations of the lines of the bit line pair do not occur independently from each other. Accordingly, reductions in the yield and reliability of the SRAM cells are less likely to occur, requiring less design margin; therefore, degradation in the performance, such as a decrease in the operating speed of the semiconductor memory device, can be reduced.

In each first SRAM cell C1, the power supply line 71 for supplying the power supply voltage VDD is formed in the M1 interconnect layer between the lines 72 and 73 corresponding to the bit lines BLB and BL, respectively. In each second SRAM cell C2, the power supply line 211 for supplying the power supply voltage VDD is formed in the BM0 interconnect layer between the lines 212 and 213 corresponding to the bit lines BLB and BL, respectively. This reduces the crosstalk noise between the lines corresponding to the bit lines BLB and BL in the first SRAM cells C1 and the second SRAM cells C2, which can reduce degradation in the performance and decrease in the reliability of the semiconductor memory device.

The BM0 interconnect layer is provided with the power supply lines 12 and 13 extending in the Y-direction and supplying the power supply voltage VSS. The BM1 interconnect layer is provided with the plurality of power supply lines 121 extending in the X-direction and supplying the power supply voltage VSS. The power supply lines 12 and 13 are connected to the power supply lines 121. Accordingly, the BM0 interconnect layer and the BM1 interconnect layer are provided with mesh-like power supply lines for supplying the power supply voltage VSS. This reduces the line resistances of the lines for supplying the power supply voltage and reduces the fluctuation of the power supply voltage, and can thus reduce lowering of the operating speed of the semiconductor memory device and increase the stability of the operation. The lines in the BM1 interconnect layer are aligned in the X-direction in the order of the power supply line 12, the power supply line 11, the power supply line 13, the line 213, the power supply line 211, and the line 212 from the left to the right in the drawings. Accordingly, the lines 212 and 213 corresponding to the bit lines BLB and BL, respectively, are not positioned adjacent to each other within each SRAM cell and between the adjacent SRAM cells; therefore, crosstalk noise between the lines corresponding to the bit lines BLB and BL is reduced, thereby reducing degradation in the performance and reliability of the semiconductor memory device.

The lines in the M1 interconnect layer are aligned in the X-direction in the order of the line 72, the power supply line 71, the line 73, the power supply line 273, the power supply line 271, and the power supply line 272 from the left to the right in the drawings. Accordingly, the lines 72 and 73 corresponding to the bit lines BLB and BL, respectively, are not positioned adjacent to each other within each SRAM cell and between the adjacent SRAM cells; therefore, crosstalk noise between the lines corresponding to the bit lines BLB and BL is reduced, thereby reducing degradation in the performance and reliability of the semiconductor memory device.

The power supply lines on the back of the transistors described above may be configured using a semiconductor chip different from the semiconductor chip in which the transistor is formed.

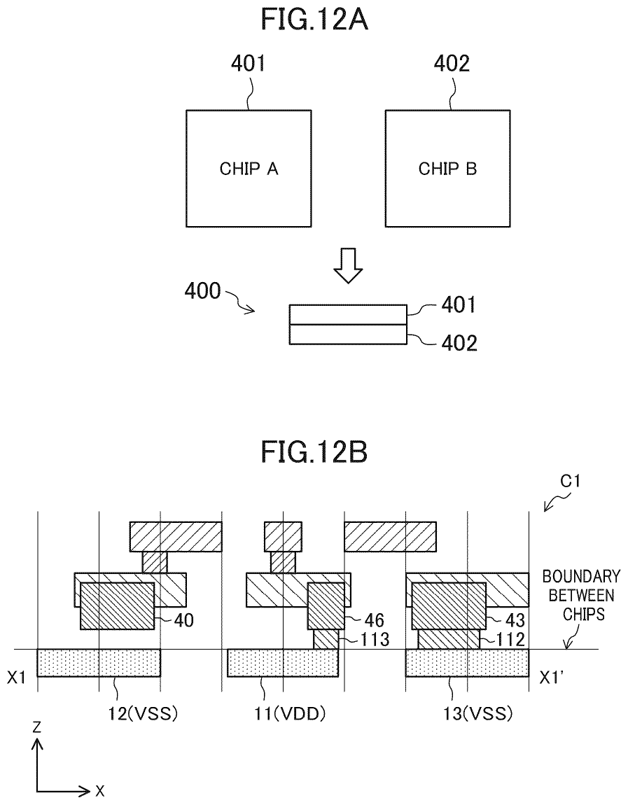

FIG. 12A shows another configuration example of the semiconductor integrated circuit device according to the embodiment. A semiconductor integrated circuit device 400 shown in FIG. 12A is formed of a first semiconductor chip 401 (i.e., a chip A) and a second semiconductor chip 402 (i.e., a chip B) stacked on each other. The SRAM cell and other components described above are arranged on the chip A. The chip B is provided with the power supply lines in an interconnect layer on the front. The chip B is bonded to the back of the chip A, using bumps or other means.

FIG. 12B illustrates a section of the first SRAM cell C1 of FIG. 1 taken along the line X1-X1′ in this configuration example. As shown in FIG. 12B, the interconnect layer on the front of the chip B is provided with the power supply line 11 for supplying VDD and the power supply lines 12 and 13 for supplying VSS. The power supply line 11 is connected to the region 46 of the chip A through the via 113 provided at a position overlapping the power supply line 11 in plan view. The power supply line 13 is connected to the region 43 of the chip A through the via 112 provided at a position overlapping the power supply line 13 in plan view. Although not shown, the power supply line 12 is connected to the region 42 of the chip A through the via 111 provided at a position overlapping the power supply line 12 in plan view. In this case, although not shown, the power supply line 211 and the lines 212 and 213 of each second SRAM cell C2 are also formed in the interconnect layer provided on the front of the chip B, similarly to the power supply lines 11 to 13 of each first SRAM cell C1.

### First Variation

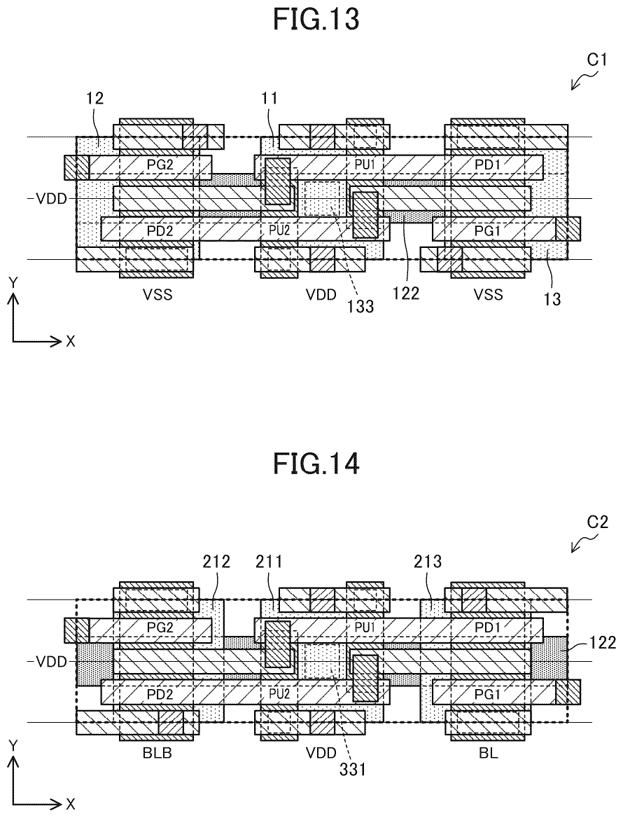

FIG. 13 is a plan view of still another example layout structure of the first SRAM cell according to the embodiment. FIG. 14 is a plan view of still another example layout structure of the second SRAM cell according to the embodiment. Specifically, FIG. 13 shows a cell lower portion of the first SRAM cell C1, and FIG. 14 shows a cell lower portion of the second SRAM cell C2. In this variation, the upper portion of the first SRAM cell C1 in FIG. 13 is the same as in (a) of FIG. 1, and the upper portion of the second SRAM cell C2 in FIG. 14 is the same as in (a) of FIG. 5.

In FIGS. 13 and 14, compared with FIGS. 1 and 5, respectively, a power supply line 122 is formed in the BM1 interconnect layer instead of the power supply line 121.

Specifically, the BM1 interconnect layer is provided with the power supply line 122 extending in the X-direction. The power supply line 122 supplies the power supply voltage VDD. In the first SRAM cell C1 of FIG. 13, the power supply line 122 is connected to the power supply line 11 in the BM0 interconnect layer through a via 133. In the second SRAM cell C2 of FIG. 14, the power supply line 122 is connected to the power supply line 211 in the BM0 interconnect layer through a via 331.

When the first SRAM cells C1 of FIG. 13 and the second SRAM cells C2 of FIG. 14 are arranged in the circuit blocks of FIGS. 8 and 9, multiple power supply lines 122 are aligned in the Y-direction in the BM1 interconnect layer.

This variation can enhance the power supply voltage VDD to be supplied to the first SRAM cells C1 and the second SRAM cells C2.

In addition, the advantages similar to those of FIGS. 1 and 5 can be obtained.

In the circuit block of FIGS. 8 and 9, some or all of the first SRAM cells C1 of FIG. 1 and the second SRAM cells C2 of FIG. 5 may be replaced with the first SRAM cells C1 of FIG. 13 and the second SRAM cells C2 of FIG. 14. In this case, for example, the first SRAM cells C1 of FIG. 1 and the second SRAM cells C2 of FIG. 5 may be replaced, every N rows in the Y-direction (where N is an integer of two or more), with the first SRAM cells C1 of FIG. 13 and the second SRAM cells C2 of FIG. 14.

### Second Variation

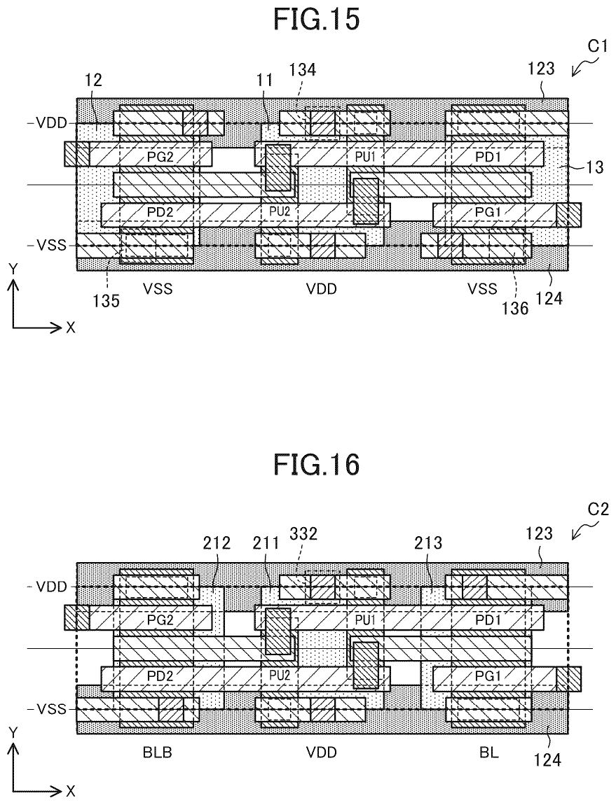

FIG. 15 is a plan view of still another example layout structure of the first SRAM cell according to the embodiment. FIG. 16 is a plan view of still another example layout structure of the second SRAM cell according to the embodiment. Specifically, FIG. 15 shows a cell lower portion of the first SRAM cell C1, and FIG. 16 shows a cell lower portion of the second SRAM cell C2. In this variation, the upper portion of the first SRAM cell C1 in FIG. 15 is the same as in (a) of FIG. 1, and the upper portion of the second SRAM cell C2 in FIG. 16 is the same as in (a) of FIG. 5.

In FIGS. 15 and 16, compared with FIGS. 1 and 5, respectively, power supply lines 123 and 124 are formed in the BM1 interconnect layer instead of the power supply line 121.

Specifically, the BM1 interconnect layer is provided with the power supply lines 123 and 124 extending in the X-direction. The power supply line 123 is formed at the upper end of the drawings and supplies the power supply voltage VDD. The power supply line 124 is formed at the lower end of the drawings and supplies the power supply voltage VSS. In the first SRAM cell C1 of FIG. 15, the power supply line 123 is connected to the power supply line 11 of the BM0 interconnect layer through a via 134. In the first SRAM cell C1 of FIG. 15, the power supply line 124 is connected to the power supply line 12 in the BM0 interconnect layer through a via 135, and connected to the power supply line 13 in the BM0 interconnect layer through a via 136. In the second SRAM cell C2 of FIG. 16, the power supply line 123 is connected to the power supply line 211 in the BM0 interconnect layer through a via 332.

When the first SRAM cells C1 of FIG. 15 and the second SRAM cells C2 of FIG. 16 are arranged in the circuit blocks of FIGS. 8 and 9, the power supply lines 123 and 124 are aligned alternately in the Y-direction in the BM1 interconnect layer.

This variation can enhance the power supply voltages VDD and VSS to be supplied to the first SRAM cells C1 and the second SRAM cells C2.

In addition, the advantages similar to those of FIGS. 1 and 5 can be obtained.

In FIGS. 15 and 16, the power supply lines 123 and 124 are formed at the upper end and the lower end of the drawings, but are not limited thereto. The power supply lines 123 and 124 may have the same line width or different line widths.

In the embodiment and its variations described above, the first SRAM cell C1 includes, in the BM0 interconnect layer and the M1 interconnect layer, the power supply lines 11 and 71 for supplying the power supply voltage VDD, respectively. However, at least one of the power supply line 11 or the power supply line 71 may suffice. For example, when only the power supply line 71 of the M1 interconnect layer is formed, the line widths of the power supply lines 12 and 13 in the BM0 interconnect layer for supplying the power supply voltage VSS can be increased; it is thus possible to enhance the power supply voltage VSS to be supplied to the first SRAM cells C1. On the other hand, when only the power supply line 11 of the BM0 interconnect layer is formed, the line widths of the lines 72 and 73 in the M1 interconnect layer, corresponding to the bit lines BLB and BL, can be increased; it is thus possible to reduce line resistances of the bit lines and reduce lowering of the operating speed of the semiconductor memory device.

In the embodiment and its variations described above, the second SRAM cell C2 includes, in the BM0 interconnect layer and the M1 interconnect layer, the power supply lines 211 and 271 for supplying the power supply voltage VDD, respectively. However, at least one of the power supply line 211 or the power supply line 271 may suffice. For example, when only the power supply line 211 of the BM0 interconnect layer is formed, the line widths of the power supply lines 272 and 273 in the M1 interconnect layer for supplying the power supply voltage VSS can be increased; it is thus possible to enhance the power supply voltage VSS to be supplied to the second SRAM cells C2. On the other hand, when only the power supply line 271 of the M1 interconnect layer is formed, the line widths of the lines 212 and 213 in the BM0 interconnect layer, corresponding to the bit lines BLB and BL, can be increased; it is thus possible to reduce line resistances of the bit lines and reduce lowering of the operating speed of the semiconductor memory device.

In the above embodiments and variations, each transistor includes three nanosheets, but some or all of the transistors may include one, two, four, or more nanosheets.

In the above embodiments and variations, the sectional shape of the nanosheet is rectangular, but is not limited thereto. For example, the shape may be square, circular, or elliptical.

In the above embodiments and variations, the widths of the nanosheets 21 to 24 in the X-direction is twice the widths of the nanosheets 25 and 26 in the X-direction, but are not limited thereto. The widths of the nanosheets 21 to 26 in the X-direction may be determined in view of the operational stability and other capabilities of the SRAM circuit.

In the above embodiment and variations, the shared-contacts 61 and 62 may be manufactured in the same process as that for the contacts (Gate-Contact) and the local lines, or may be manufactured in different processes.

In the embodiment and variations described above, the power sources for supplying the power supply voltage VDD to the sources (i.e., the regions 46 and 49) of the load transistors PU1 and PU2 in the first SRAM cell C1 and the sources (i.e., the regions 246 and 249) of the load transistors PU1 and PU2 in the second SRAM cell C2 are not limited to the power sources supplied from the outside of the semiconductor integrated circuit, and may be power sources generated inside the semiconductor integrated circuit, power sources generated inside the semiconductor memory device, or any other suitable type of power sources.

The present disclosure provides a layout structure of an SRAM cell with a line on the back of a transistor, which can reduce a degradation in the performance of a semiconductor memory device.

### DESCRIPTION OF REFERENCE CHARACTERS

11 to 13, 71, 121 to 124, 211, 271 to 273 Power Supply Line
111 to 114, 311 to 314 Via
21 to 26 Nanosheet
31 to 34 Gate Line
40 to 49, 240 to 249 Region
72, 73, 212, 213 Line
C1 First SRAM Cell
C2 Second SRAM Cell
PU1, PU2 Load Transistor
PD1, PD2 Drive Transistor
PG1, PG2 Access Transistor
BL, BLB Bit Line
WL Word Line

What is claimed is:

1. A semiconductor memory device including a plurality of SRAM cells,
each of the SRAM cells comprising:
a first transistor having a source connected to a first power source for supplying a first power supply voltage, a drain connected to a first node, and a gate connected to a second node;
a second transistor having a source connected to the first power source, a drain connected to the second node, and a gate connected to the first node;
a third transistor having a source connected to a second power source for supplying a second power supply voltage different from the first power supply voltage, a drain connected to the first node, and a gate connected to the second node;
a fourth transistor having a source connected to the second power source, a drain connected to the second node, and a gate connected to the first node;
a fifth transistor having a source connected to a first bit line, a drain connected to the first node, and a gate connected to a word line; and
a sixth transistor having a source connected to a second bit line forming a complementary bit line pair together with the first bit line, a drain connected to the second node, and a gate connected to the word line,
the plurality of SRAM cells including:
a first SRAM cell; and
a second SRAM cell aligned with the first SRAM cell in a first direction,
the first bit line of the first SRAM cell including a first line formed in a metal interconnect layer above the first to sixth transistors, the first line extending in a second direction,
the second bit line of the first SRAM cell including a second line formed in the metal interconnect layer, the second line extending in the second direction,
the first SRAM cell comprising:
a first active region forming a channel, the source, and the drain of the third transistor of the first SRAM cell, and including a nanosheet extending in the second direction as the channel;
a second active region forming a channel, the source, and the drain of the fourth transistor of the first SRAM cell, and including a nanosheet extending in the second direction as the channel;
a first power supply line formed in a first back interconnect layer on a back side of the first to sixth transistors, the first power supply line extending in the second direction and connected to the second power source;
a second power supply line formed in the first back interconnect layer, the second power supply line extending in the second direction and connected to the second power source;
a first via arranged at a position where a first region forming the source of the third transistor in the first active region and the first power supply line overlap each other, the first via connecting the first region and the first power supply line; and
a second via arranged at a position where a second region forming the source of the fourth transistor in the second active region and the second power supply line overlap each other, the second via connecting the second region and the second power supply line,
the first bit line of the second SRAM cell including a third line formed in the first back interconnect layer, the third line extending in the second direction,
the second bit line of the second SRAM cell including a fourth line formed in the first back interconnect layer, the fourth line extending in the second direction,
the second SRAM cell comprising:
a third active region forming a channel, the source, and the drain of the third transistor of the second SRAM cell, and including a nanosheet extending in the second direction as the channel;
a fourth active region forming a channel, the source, and the drain of the fourth transistor of the second SRAM cell, and including a nanosheet extending in the second direction as the channel;
a third via arranged at a position where a third region forming the source of the third transistor in the third active region and the third line overlap each other, the third via connecting the third region and the third line;
a fourth via arranged at a position where a fourth region forming the source of the fourth transistor in the fourth active region and the fourth line overlap each other, the fourth via connecting the fourth region and the fourth line; and
a third power supply line formed in the metal interconnect layer, the third power supply line extending in the second direction and connected to the second power source.

2. The semiconductor memory device of claim 1, wherein
the first SRAM cell further comprises a fourth power supply line formed in the metal interconnect layer, the fourth power supply line extending in the second direction, formed between the first and second lines, and connected to the first power source.

3. The semiconductor memory device of claim 1, wherein
the first SRAM cell further comprises:
a fifth active region forming a channel, the source, and the drain of the first transistor of the first SRAM cell, and including a nanosheet extending in the second direction as the channel;
a sixth active region forming a channel, the source, and the drain of the second transistor of the first SRAM cell, and including a nanosheet extending in the second direction as the channel;
a fifth power supply line formed in the first back interconnect layer, the fifth power supply line extending in the second direction and connected to the first power source;
a fifth via arranged at a position where a fifth region forming the source of the first transistor in the fifth active region and the fifth power supply line overlap each other, the fifth via connecting the fifth region and the fifth power supply line; and
a sixth via arranged at a position where a sixth region forming the source of the second transistor in the sixth active region and the fifth power supply line overlap each other, the sixth via connecting the sixth region and the fifth power supply line.

4. The semiconductor memory device of claim 1, wherein
the second SRAM cell further comprises:
a sixth power supply line formed in the metal interconnect layer, the sixth power supply line extending in the second direction and connected to the second power source; and
a seventh power supply line formed in the metal interconnect layer, the seventh power supply line extending in the second direction, formed between the third and sixth power supply lines, and connected to the first power source.

5. The semiconductor memory device of claim 1, wherein
the second SRAM cell further comprises:
a seventh active region forming a channel, the source, and the drain of the first transistor of the second SRAM cell, and including a nanosheet extending in the second direction as the channel;
an eighth active region forming a channel, the source, and the drain of the second transistor of the second SRAM cell, and including a nanosheet extending in the second direction as the channel;
an eighth power supply line formed in the first back interconnect layer, the eighth power supply line extending in the second direction and connected to the first power source;
a seventh via arranged at a position where a seventh region forming the source of the first transistor in the seventh active region and the eighth power supply line overlap each other, the seventh via connecting the seventh region and the eighth power supply line; and
an eighth via arranged at a position where an eighth region forming the source of the second transistor in the eighth active region and the eighth power supply line overlap each other, the eighth via connecting the eighth region and the eighth power supply line.

6. The semiconductor memory device of claim 1, wherein
each of the plurality of SRAM cells further comprises a ninth power supply line formed in a second back interconnect layer below the first back interconnect layer, the ninth power supply line extending in the first direction and connected to the first and second power supply lines.

7. The semiconductor memory device of claim 1, wherein
the first SRAM cell further comprises a fourth power supply line formed in the metal interconnect layer, the fourth power supply line extending in the second direction, formed between the first and second lines, and connected to the first power source,
the second SRAM cell further comprises:
a sixth power supply line formed in the metal interconnect layer, the sixth power supply line extending in the second direction and connected to the second power source; and
a seventh power supply line formed in the metal interconnect layer, the seventh power supply line extending in the second direction, formed between the third and sixth power supply lines, and connected to the first power source,
in the plurality of SRAM cells, first cell rows and second cell rows are aligned alternately in the first direction, each of the first cell rows including a plurality of first SRAM cells aligned in the second direction, each of the first SRAM cells being identical to the first SRAM cell, each of the second cell rows including a plurality of second SRAM cells aligned in the second direction, each of the second SRAM cells being identical to the second SRAM cell,
in each of the first cell rows, the plurality of first SRAM cells are connected in common to the same first line, the same second line, and the same fourth power supply line, and
in each of the second cell rows, the plurality of second SRAM cells are connected in common to the same third power supply line, the same sixth power supply line, and the same seventh power supply line.

8. The semiconductor memory device of claim 1, wherein
the first SRAM cell further comprises:
a fifth active region forming a channel, the source, and the drain of the first transistor of the first SRAM cell, and including a nanosheet extending in the second direction as the channel;
a sixth active region forming a channel, the source, and the drain of the second transistor of the first SRAM cell, and including a nanosheet extending in the second direction as the channel;
a fifth power supply line formed in the first back interconnect layer, the fifth power supply line extending in the second direction and connected to the first power source;
a fifth via arranged at a position where a fifth region forming the source of the first transistor in the fifth active region and the fifth power supply line overlap each other, the fifth via connecting the fifth region and the fifth power supply line; and
a sixth via arranged at a position where a sixth region forming the source of the second transistor in the sixth active region and the fifth power supply line overlap each other, the sixth via connecting the sixth region and the fifth power supply line,
the second SRAM cell further comprises:
a seventh active region forming a channel, the source, and the drain of the first transistor of the second SRAM cell, and including a nanosheet extending in the second direction as the channel;
an eighth active region forming a channel, the source, and the drain of the second transistor of the second SRAM cell, and including a nanosheet extending in the second direction as the channel;
an eighth power supply line formed in the first back interconnect layer, the eighth power supply line extending in the second direction and connected to the first power source;
a seventh via arranged at a position where a seventh region forming the source of the first transistor in the seventh active region and the eighth power supply line overlap each other, the seventh via connecting the seventh region and the eighth power supply line; and
an eighth via arranged at a position where an eighth region forming the source of the second transistor in the eighth active region and the eighth power supply line overlap each other, the eighth via connecting the eighth region and the eighth power supply line,
in the plurality of SRAM cells, first cell rows and second cell rows are aligned alternately in the first direction, each of the first cell rows including a plurality of first SRAM cells aligned in the second direction, each of the first SRAM cells being identical to the first SRAM cell, each of the second cell rows including a plurality of second SRAM cells aligned in the second direction, each of the second SRAM cells being identical to the second SRAM cell,
in each of the first cell rows, the plurality of first SRAM cells are connected in common to the same first power supply line, the same second power supply line, and the same fifth power supply line, and
in each of the second cell rows, the plurality of second SRAM cells are connected in common to the same third line, the same fourth line, and the same eighth power supply line.

9. The semiconductor memory device of claim 8, wherein
the plurality of SRAM cells comprises:
a plurality of ninth power supply lines formed in a second back interconnect layer below the first back interconnect layer, the ninth power supply lines extending in the first direction and connected to the second power source, and
the first and second power supply lines for the first SRAM cells aligned in the first direction are connected in common to the same one of the plurality of ninth power supply lines.

10. The semiconductor memory device of claim 1, wherein
the first SRAM cell further comprises:
a fifth active region forming a channel, the source, and the drain of the first transistor of the first SRAM cell, and including a nanosheet extending in the second direction as the channel;
a sixth active region forming a channel, the source, and the drain of the second transistor of the first SRAM cell, and including a nanosheet extending in the second direction as the channel;
a fifth power supply line formed in the first back interconnect layer, the fifth power supply line extending in the second direction and connected to the first power source;
a fifth via arranged at a position where a fifth region forming the source of the first transistor in the fifth active region and the fifth power supply line overlap each other, the fifth via connecting the fifth region and the fifth power supply line; and
a sixth via arranged at a position where a sixth region forming the source of the second transistor in the sixth active region and the fifth power supply line overlap each other, the sixth via connecting the sixth region and the fifth power supply line,
the second SRAM cell further comprises:
a seventh active region forming a channel, the source, and the drain of the first transistor of the second SRAM cell, and including a nanosheet extending in the second direction as the channel;
an eighth active region forming a channel, the source, and the drain of the second transistor of the second SRAM cell, and including a nanosheet extending in the second direction as the channel;
an eighth power supply line formed in the first back interconnect layer, the eighth power supply line extending in the second direction and connected to the first power source;
a seventh via arranged at a position where a seventh region forming the source of the first transistor in the seventh active region and the eighth power supply line overlap each other, the seventh via connecting the seventh region and the eighth power supply line; and
an eighth via arranged at a position where an eighth region forming the source of the second transistor in the eighth active region and the eighth power supply line overlap each other, the eighth via connecting the eighth region and the eighth power supply line,
each of the plurality of SRAM cells further comprises a tenth power supply line formed in a second back interconnect layer below the first back interconnect layer, the tenth power supply line extending in the first direction and connected to the fifth and eighth power supply lines.

11. The semiconductor memory device of claim 10, wherein
each of the plurality of SRAM cells further comprises a ninth power supply line formed in the second back interconnect layer, the ninth power supply line extending in the first direction and connected to the first and second power supply lines.
